(19) United States
(12) Patent Application Publication
(10) Pub. No.: US 2026/0242928 A1
(43) Pub. Date: Aug. 20, 2026

(54) SINGLE NEUTRALIZER FOR DUAL ION BEAM SYSTEM

(71) Applicant: VEECO INSTRUMENTS INC., Plainview, NY (US)

(72) Inventors: Mathew LEVOSO, Plainview, NY (US); John ADAMO, Plainview, NY (US); Binyamin RUBIN, Plainview, NY (US)

(21) Appl. No.: 19/451,950

(22) Filed: Jan. 16, 2026

Related U.S. Application Data
(60) Provisional application No. 63/761,088, filed on Feb. 20, 2025.

(51) Int. Cl. C23C 14/22

(52) U.S. Cl. CPC C23C 14/221

(57) ABSTRACT

The present disclosure provides an assisted ion beam deposition system with a single neutralization source or neutralizer used for both the deposition ion source and the assist ion source. In some embodiments, the assisted ion beam deposition system has only this one neutralizer. This one neutralizer provides the ignition and the beam neutralization for both ion sources. Having one neutralizer saves physical space in the system and lowers power usage.

### CROSS-REFERENCE

This application claims priority to U.S. provisional application 63/761,088 filed February 20, 2025, the entire disclosure of which is incorporated herein by reference for all purposes.

### BACKGROUND

In assisted ion beam deposition (AIBD), also referred to as ion beam deposition (IBD) with assist, the standard approach is to have two ion sources, with one source serving as a sputtering ion source for deposition and the other source fulfilling the role of assisting or reactive plasma generation to facilitate the deposition process. Using an assist ion source has multiple advantages, enabling the optimization of deposited film properties, such as microstructure and stoichiometry.

Each of the sources, the deposition ion source and the assist ion source, has its own ion neutralizer, used for igniting the respective source and neutralizing the resulting ion beam, if needed or desired.

### SUMMARY

The present disclosure describes an assisted ion beam deposition system featuring a single neutralizer that serves both the deposition ion source and the assist ion source. This one neutralizer provides the electrons for enabling the plasma ignition and provides the beam neutralization for both ion sources. Having one neutralizer saves physical space in the system, lowers power usage, and decreases the overall cost of the system.

In one particular implementation, this disclosure provides an ion beam deposition system having a deposition system comprising a deposition beam source, an assist system comprising an assist beam source, and one neutralizer configured to provide low-energy electrons to the deposition system and to the assist system. In some embodiments, a second neutralizer is present to provide low-energy electrons to another ion source.

In another particular implementation, this disclosure provides an ion beam deposition system having a first ion beam source, a second ion beam source, and a neutralizer configured to, upon receipt of a request, independently (1) provide low-energy electrons to the first ion beam source to enable production of a first ion beam, (2) provide low-energy electrons to the second ion beam source to enable production of a second ion beam, (3) neutralize the first ion beam, and (4) neutralize the second ion beam.

In yet another particular implementation, this disclosure provides a neutralizer configured to, upon receipt of a request, enable igniting a plasma to produce an ion beam from a deposition beam source, enable igniting a second plasma to produce an assist beam from an assist beam source, neutralize the deposition ion beam, and neutralize the assist beam.

In yet another particular implementation, this disclosure provides a method of neutralizing both a first ion beam and a second ion beam with the same neutralizer, meaning, with electrons from the same electron source. The same neutralizer can also be used for igniting the plasma for producing those ion beams. In some methods, a second neutralizer is used to neutralize a third ion beam and ignite the plasma producing that beam.

These and other aspects of the neutralizer and system described herein will be apparent after consideration of the Detailed Description and Figures herein. It is to be understood, however, that the scope of the claimed subject matter shall be determined by the claims as issued and not by whether given subject matter addresses any or all issues noted in the Background or includes any features or aspects recited in the Summary.

### BRIEF DESCRIPTION OF THE FIGURES

FIG. 1 is a schematic view of an ion beam deposition system featuring an ion deposition source and an assist ion source, each source equipped with its own neutralizer.

FIG. 2 is a schematic diagram of space charge compensation of an ion beam by a neutralizer.

FIG. 3 is a schematic view of an ion beam deposition system with an ion deposition source and an assist ion source, the system having only one neutralizer.

FIG. 4 is a schematic block diagram of an ion beam system having two ion beam sources and only one neutralizer shown generating electrons.

### DETAILED DESCRIPTION

As indicated above, the present disclosure describes assist ion beam deposition systems having a single neutralization source or neutralizer used for both the ion deposition source and the assist ion source.

Standard assisted ion beam deposition (AIBD) utilizes two ion sources, with one serving as a sputtering ion source for deposition and the other providing assistance or generating reactive plasma for etching, modifying, or otherwise facilitating the deposition process.

During ion beam deposition processes, both the deposition/sputtering operation and the etch/assist operation utilize positively charged ions produced by respective sources. To prevent high beam divergence and positive surface charging, each ion beam is neutralized; an electron emitter, often referred to as a neutralizer, is used. In these systems, each ion source, the deposition ion source and the assist ion source, typically has a separate electron emitter/neutralizer.

In an ion beam system, positive ions from the ion source, either the deposition ion source or the assist ion source, create positive potential that attracts electrons to the areas that need neutralization. The electrons provide space charge compensation, meaning that in any given volume, there is net zero charge; i.e., the density of positive ions is equal to the density of negative electrons. In some embodiments, neutralization of the beam from the deposition source with electrons is not needed; in most embodiments, neutralization of the beam from the assist source is desired.

In addition to neutralizing the beam, neutralizers provide electrons, sometimes referred to as seed electrons, that enable the ignition of the plasma required to form or produce the ion beam, for both the deposition and assist ion sources.

In systems of this disclosure, however, a single neutralizer is used to neutralize both ion beams and/or provide electrons, as needed. Having a single neutralizer reduces system cost and required maintenance, simplifies the control system, and improves reliability.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

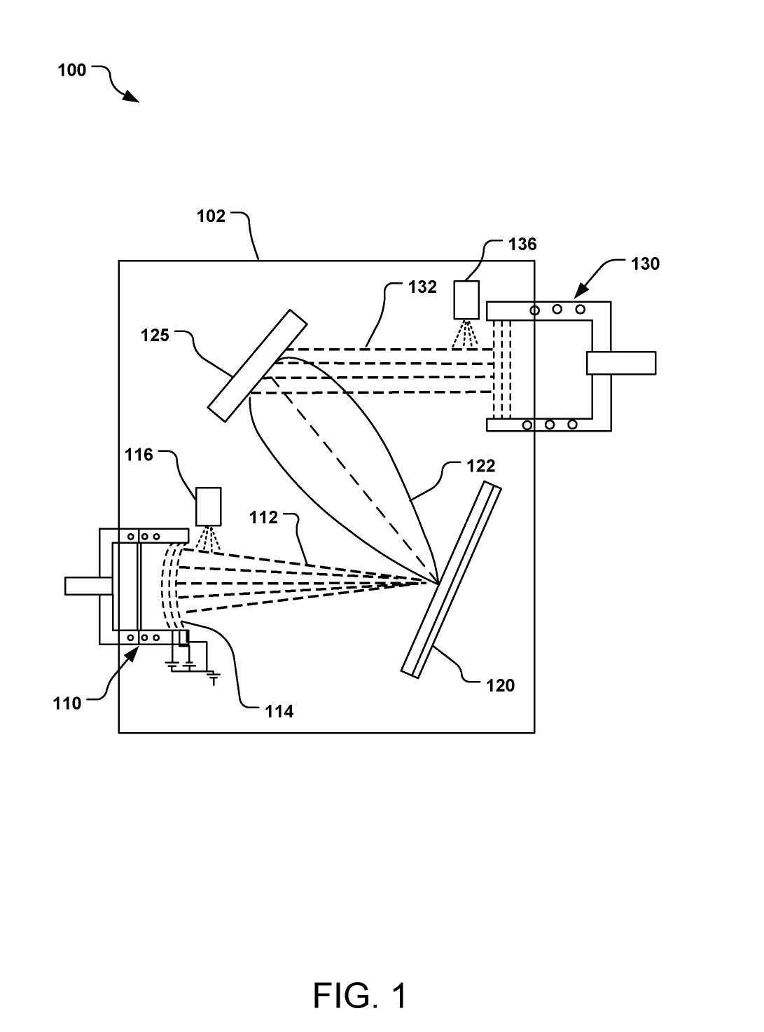

Turning to the figures, FIG. 1 shows a system 100 that includes an ion beam deposition (IBD) system and an assist ion or ion beam system. The system 100 includes various elements from a conventional IBD system, such as a vacuum chamber 102 having therein a deposition system 110 and an assist ion system 130. Also present in the chamber 102 of the system 100 is a target 120 and a substrate 125 to be coated. The target 120 provides the material to be deposited (sputtered) onto the substrate 125 and may be, for example, a metal or metal oxide. The substrate 125 may be a silicon or glass wafer and/or may have, for example, one or multiple layers of silicide(s), nitride(s), oxide(s), metal(s) including alloys, or ceramic(s).

The deposition system 110 has an ion beam source that generates an ion beam 112, which can include a plurality of ion beamlets targeted or directed toward the target 120. A source gas is used in the ion source and is typically a noble gas such as helium, xenon, argon, or krypton.

The system 110 includes one or more grids 114 proximate the ion beam source for directing the ion beam 112 from the ion beam source to the target 120. The ion beam 112, upon striking the target 120, generates a sputter plume 122 of material from the target 120. The ion beam 112 strikes the target 120 at such an angle that the sputter plume 122 generated from the target 120 travels towards the substrate 125. The sputter plume 122 may be made more or less concentrated so that its resulting deposition of material on the substrate 125 is more effectively distributed over a particular area of the substrate 125.

The deposition system 110 includes a neutralizer 116 for generating electrons, e.g., low-energy electrons, to ignite the plasma, thereby forming or producing the ion beam 112. The neutralizer 116 may be, for example, a filament-based neutralizer, including a hot-filament, plasma bridge neutralizer (PBN), or an RF neutralizer. In some embodiments, a hollow-cathode type neutralizer may be used. Such neutralizers, their components, and mode of operation are well known. The electrons from the neutralizer 116 may also be used to provide space charge compensation, which means, in any given volume, there is net zero charge to the ion beam 112. In some embodiments, neutralization of the beam from the deposition source is not needed because, as the ions strike the target 120, secondary electrons are generated, providing neutralization to the ion beam 112.

The system 100 also includes an assist ion beam system 130 that provides a source of ions that bombards the substrate 125 so that material deposited on the substrate 125 by the deposition system 110 is removed or modified. The assist ion beam system 130 may be referred to an ion beam etching system or the like. The assist ion beam system 130 includes an ion beam source that generates an assist ion beam 132 that includes a plurality of ion beamlets targeted or directed toward the substrate 125. The assist ion beam 132 controls the net amount of material deposited on the substrate 125 by the sputter plume 122. In some implementations, the assist ion beam 132 modifies the material that is being deposited by the sputter plume 122.

The assist ion beam system 130 includes a neutralizer 136 for generating electrons, e.g., low-energy electrons, to enable ignition of the plasma thus forming or producing the assist beam 132. The neutralizer 136 may be, for example, a filament-based neutralizer, including a hot-filament, plasma bridge neutralizer (PBN), or an RF neutralizer, or a hollow-cathode type neutralizer. Such neutralizers, their components, and mode of operation are well known. The electrons from the neutralizer 136 can also provide space charge compensation to the assist ion beam 132.

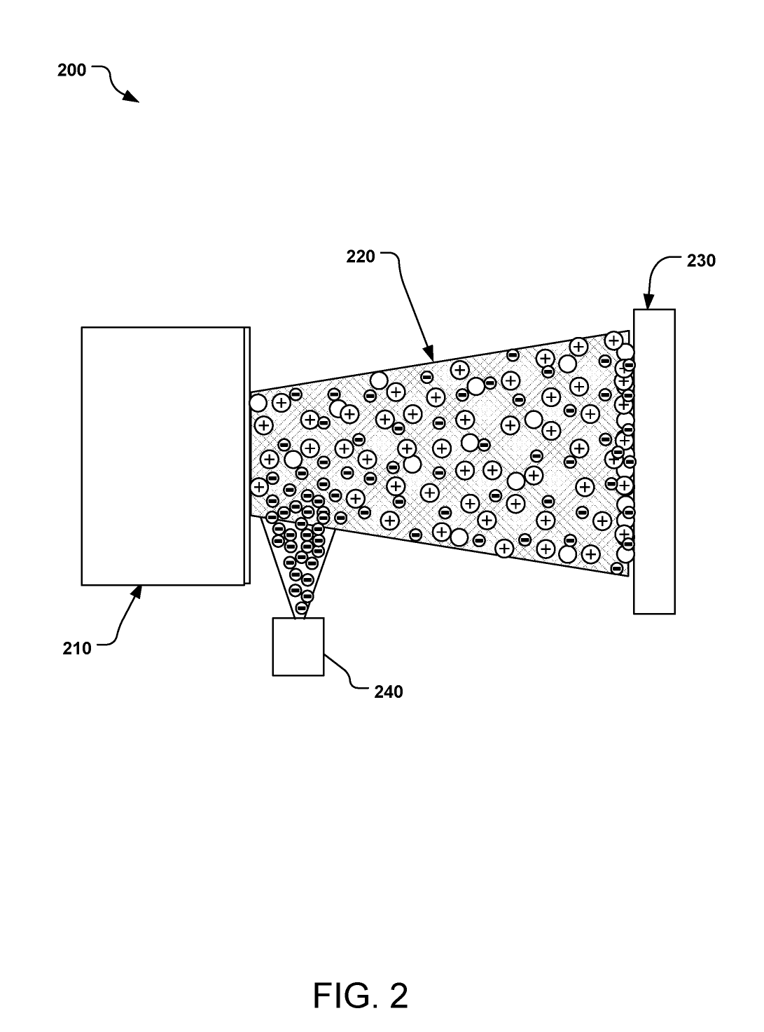

FIG. 2 illustrates space charge compensation of an ion beam (either a deposition ion beam or an assist ion beam) by a neutralizer. A system 200 has a generic ion source 210 from which emanates a beam 220 onto a target 230. The system 200 also includes a neutralizer 240 that generates electrons, e.g., low-energy electrons.

The beam 220 from the source 210 is composed of positively charged ions (+) and inert or neutral gas atoms (O). The neutralizer 240 generates electrons (-) that balance the positively charged ions (+), thus neutralizing the surface of the target 230.

Returning to FIG. 1, the target 120 is positioned so that the ion beam 112 strikes the target 120 at a desired angle. The target 120 can be attached to a fixture (not called out) that allows the target 120 to be rotated or moved in a desired manner, including rotation of the entire target about an axis or pivoting of the target 120 in relation to the axis. Additionally or alternately, the substrate 125 can be pivotable in relation to the target 120 and to the assist ion beam system 130.

Those skilled in the art will appreciate that the relative positions of the sputter plume 122 and the assist ion beam 132 can be such that the deposition angle and the etch angle can be adjusted over a range of angles depending on the required or desired film properties. Additionally, the skilled artisan will appreciate that by tilting the substrate 125, one can position the substrate 125 in such a manner so that both the sputter plume 122 and assist beam 132 reach the substrate.

The net deposition rate of material onto the substrate 125 is affected by the sputter plume 122 and the ion assist beam 132, including the angle of the beams 112, 132 and the plume 122. In one example, a deposition angle in the range of +40 to +50 degrees, combined with an assist beam or etch angle in the range of -20 to -25 degrees, yields a net deposition rate suitable for producing thin metal films with the desired properties.

The system 100, having an IBD system and an assist ion beam, is also referred to as an ion beam deposition system with assist, an assisted ion beam deposition (AIBD) system, and variations thereof. One of its many attributes is that the system 100 allows for optimization of the deposited film properties, such as microstructure and stoichiometry.

However, the system 100 has a high cost, is complex, occupies a large volume, and has limitations. Each neutralizer, 116, 136, occupies a considerable volume, either within the vacuum chamber 102 or external to the chamber 102. Having two neutralizers 116, 136 also requires multiple power supplies, each with sophisticated controls. Moreover, the geometry of the chamber 102 represents a limiting factor, as the two ion source systems 110, 130, the two neutralizers 116, 136, the sputtering target 120 and its holding fixture, and the substrate 125 and its holding fixture all require meticulous design and alignment to ensure the necessary deposition conditions are met. For example, the relative positioning and geometry of the deposition system 110, the assist system 130, the target 120, and the substrate 125, while depending on the application, are highly limited by their size and type. For example, an unobstructed line of sight is required between the deposition system 110 and the target 120, as well as between the assist system 130 and the substrate 125.

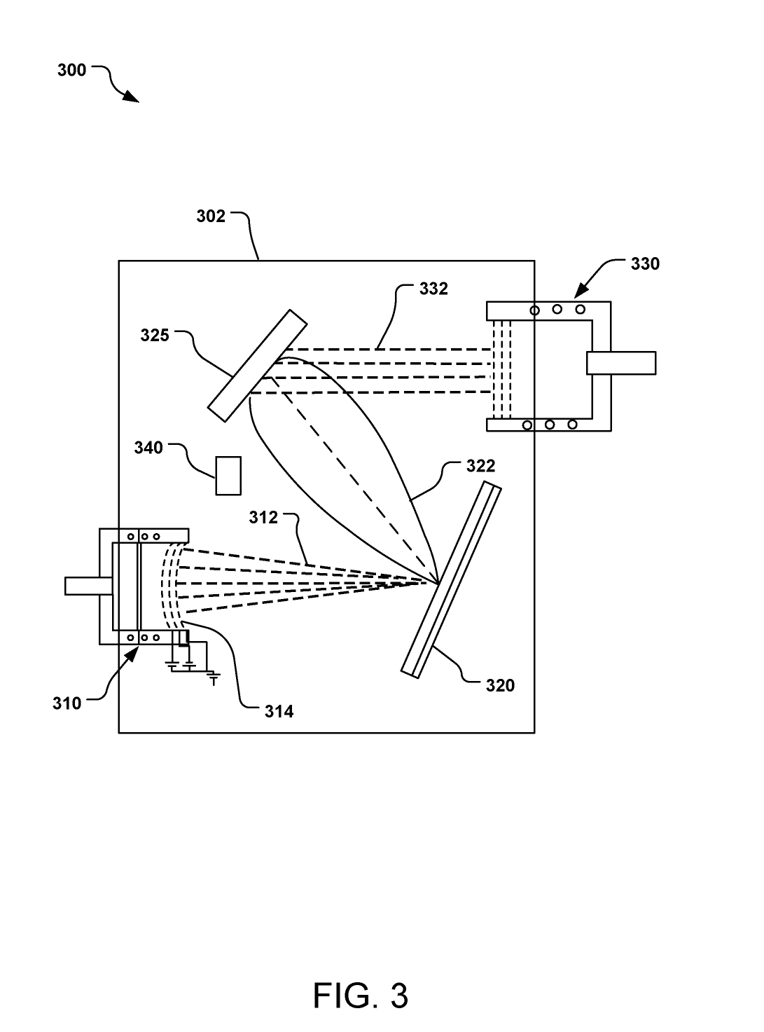

To address these limitations of an AIBD system, such as the system 100, FIG. 3 provides an alternative system 300, a dual ion beam system having a single neutralization source. Rather than having two neutralizers or neutralization sources, one for the deposition source and one for the assist source, a revised system has one neutralization source, or neutralizer, shared across both the deposition source and the assist source. The system 300 includes various elements from a conventional IBD system, such as shown in FIG. 1 as the system 100, including a vacuum chamber 302, an ion deposition system 310, a target 320, a substrate 325, and an assist system 330. Features and elements of the system 300 are the same as or similar to the system 100 of FIG. 1, unless described otherwise herein.

As with the ion deposition system 110, the ion deposition system 310 has an ion beam source that generates an ion beam 312, which can include a plurality of ion beamlets targeted or directed toward the target 320. One or more grids 314 proximate the ion beam source direct the ion beam 312 from the ion beam source to the target 320. The ion beam 312, upon striking the target 320, generates a sputter plume 322 of material from the target 320. The ion beam 312 strikes the target 320 at such an angle that the sputter plume 322 generated from the target 320 travels towards and deposits on the substrate 325.

The system 300 also includes an assist ion beam system 330 that, similar to the assist system 130, provides a source of ions that bombard the substrate 325, allowing material deposited on the substrate 325 by the deposition system 310 to be removed or modified. The assist ion beam system 330 includes an ion beam source that generates an assist ion beam 332 that includes a plurality of ion beamlets, targeted or directed toward the substrate 325. The assist ion beam 332 controls the net amount of material deposited on the substrate 325 by the sputter plume 322. In some implementations, the assist ion beam 332 modifies the material that is being deposited by the sputter plume 322.

Unlike the system 100, the system 300 includes a single neutralizer 340 that is used for ignition of both the deposition system 310 and the assist system 330 and for neutralization of both beams 312, 332. The neutralizer 340 is configured for the four operations: ignite deposition ion source, neutralize deposition beam to net zero charge, ignite assist ion source, and neutralize assist beam to net zero charge.

The neutralizer 340 generates electrons, e.g., low-energy electrons, to enable ignition of the plasma in the deposition system 310, thus enabling the formation of the ion beam 312. The neutralizer operates as part of the larger scale system to provide electrons for ignition. Other power supplies are activated to execute specific sequences that ignite plasma discharge in the ion source. The electrons from the neutralizer 340 also provide space charge compensation to the ion beam 312, thus neutralizing the beam 312. Additionally, the low-energy electrons from the neutralizer 340 enable ignition of the plasma in the assist system 330, therefore enabling the formation of the assist beam 332. The electrons from the neutralizer 340 also provide space charge compensation to the assist beam 332, thus neutralizing the beam 332.

The neutralizer 340 may be, for example, a filament-based neutralizer, including a hot-filament, plasma bridge neutralizer (PBN), or an RF neutralizer. In some embodiments, it may be a hollow-cathode type neutralizer. The components and mode of operation of the actual neutralizer 340 generally do not vary from that which is well known.

For ignition and neutralization, the neutralizer 340 features an “off” mode and two electron extraction modes, “low power” and “high power,” which can be applied independently to any of the four operations.

The sources (the deposition system 310 and the assist system 330) each have an active beam extraction mode, which is when the source performs work on the subject, i.e., the deposition system 310 acts on the target or the assist system 330 acts on the substrate. The sources may also include another mode, which may be referred to as “plasma mode.” In this third mode, the source temporarily pauses the beam extraction, for example, to perform mechanical adjustments or coordinate changes within the chamber (such as a target side change or a fixture tilt angle adjustment), or for source adjustments or coordination.

When the source, either the deposition system 310 or the assist system 330, is in extraction mode and requires continuous neutralization, the neutralizer 340 operates at the output parameters (either “low” or “high”) sufficient to neutralize the beam. When the source is in plasma mode, the output parameters of the neutralizer 340 are set for the low-power condition; the low-power extraction mode is used rather than turning off the neutralizer. This plasma mode and low neutralizer power is similar to a sleep status. When the source is off, the neutralizer is also off.

To adequately provide electrons to both the deposition system 310 and the assist system 330, the location and orientation (e.g., aiming direction) of the neutralizer 340 and the expelling electrons are carefully selected and optimized. The physical location of the neutralizer 340 is not necessarily equidistant between the two systems 310, 330, but rather, the location is dependent on the physical configuration and operating parameters of the system 310, the target 320, the substrate 325, and the system 330.

In some embodiments, the location and orientation of the neutralizer 340 are weighted more for neutralization of the assist beam than neutralization of the deposition beam or ignition. For example, the neutralizer 340 may be physically positioned and/or oriented so that the emitted electrons are focused on the ion beam from the assist system 330. Because the electrons are emitted from the neutralizer 340 not as a beam but more akin to a cloud (i.e., electrons go to under-neutralized area, or, to areas where positive space charge exists), although oriented for neutralizing the ion beam from the assist system 330, the neutralizer 340 is, nevertheless, effective at igniting and neutralizing the deposition beam from the deposition system 310 and igniting the assist beam from the assist system 330.

Additionally, to adequately ignite and neutralize both the deposition system 310 and the assist system 330, the neutralizer 340 includes control logic that receives requests from the control logic algorithms for the sources of the systems 310, 330, and provides the desired neutralizer operation required for the four operations. The source control logic algorithms are part of the overall system software that controls the entire process. Each control logic algorithm is tailored to the hardware options of the particular system and to the desired operation of the specific process.

The control logic of the neutralizer 340 aggregates the requests from and the requirements of the deposition system 310 and the assist system 330 and prioritizes the implementation thereof to the higher power requirement. The requirements of each system 310, 330 are passed through an aggregation layer of the control logic that determines the combined need of the sources that share the neutralizer 340. This aggregation logic determines the optimal methodology for providing the requested and desired electron flow.

The overall system software and the neutralizer control logic follow the algorithm for initializing the systems 310, 330, including checking the interlocks, initiating gas flow, and then igniting the neutralizer in response to a request from a source. As soon as neutralizer ignition is confirmed, it proceeds to the next step. When the point in the process is reached that requires igniting one or both ion sources, the ignition sequence is initiated according to the algorithm, including initializing the system, checking the interlocks, igniting the neutralizer 340, and then igniting the plasma.

To ignite the neutralizer 340, one or both of the control logic algorithms of the deposition system 310 and the assist system 330 sends a request to the control logic of the neutralizer 340 to provide electrons for ignition of the respective ion source (which eventually results in plasma discharge inside the ion source) pursuant to the control logic in the system software requesting ignition, e.g., based on power supply status. Similarly, one or both of the control logic algorithms of the deposition system 310 and the assist system 330 sends a request to the control logic of the neutralizer 340 to provide electrons for neutralization of the ion beam from the respective ion source pursuant to the control logic in the system software and the status of the neutralizer 340.

A general example control logic is as follows: If either source needs to be ignited, a request is sent by the source to the neutralizer to bring the neutralizer to a suitable output to enable ignition; if the neutralizer is already at an appropriate output for ignition, it remains at that output. If either source is in the extraction mode and the neutralizer is required or desired for extraction, a request is sent by the source to the neutralizer to bring the neutralizer to a suitable output for neutralizing the beam from that source; if the neutralizer is already at an appropriate output for neutralization, it remains at that output. If a source that requests neutralization is in its plasma mode, and no other sources are extracting, igniting, or otherwise requiring active neutralization, the neutralizer will be brought to or remain at a suitable low power for plasma mode. If no source is requesting electrons from the neutralizer, for ignition or neutralization, the neutralizer can be turned off.

The neutralizer 340 may provide electrons, allowing the deposition beam and the assist beam to be ignited simultaneously or sequentially. Similarly, both the deposition beam and the assist beam may be neutralized, the neutralizations initiating simultaneously or sequentially.

The different operations (i.e., ignition, neutralization, of the deposition system, of the assist system) can have different operating levels, or modes. The neutralization current can be controlled based on the deposition beam current, the assist beam current, or both. In some systems and/or operations, the neutralizer provides an electron current sufficient for neutralizing only the assist beam, while the deposition beam is self-neutralized due to the secondary electrons ejected from the target when it is hit with the energetic ions of the beam.

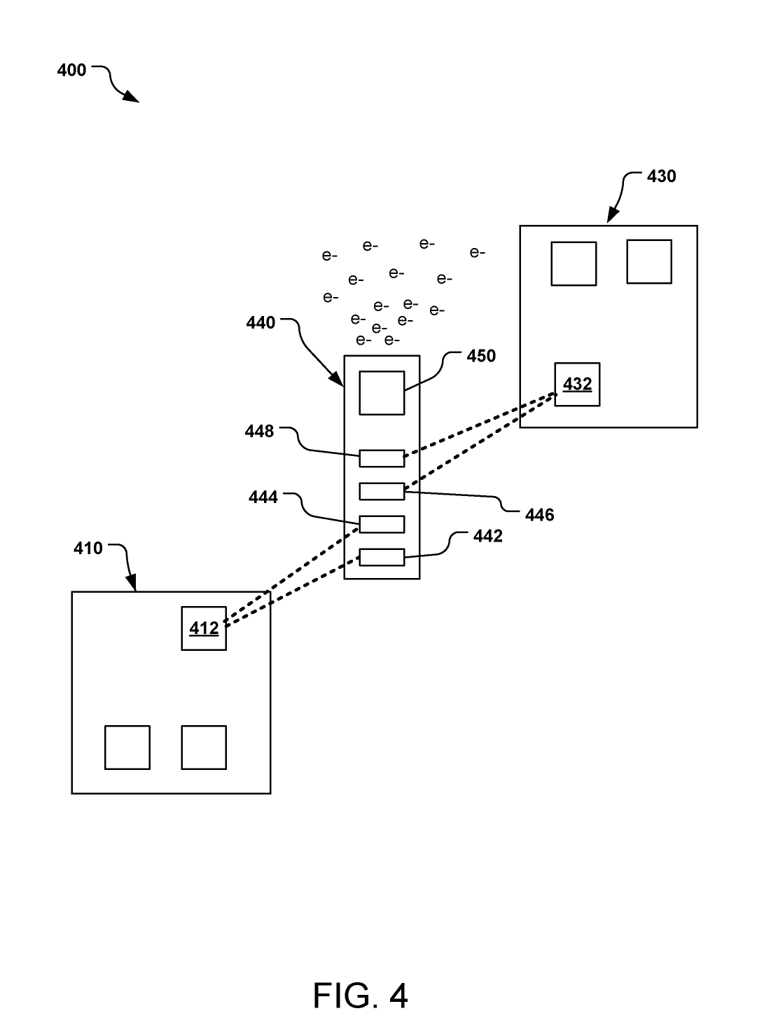

FIG. 4 schematically shows the interaction of a neutralizer with two ion sources.

A system 400 has a first ion source 410 and a second ion source 430. The first ion source 410 can be, for example, an ion deposition beam source, and the second ion source 430 can be, for example, an ion assist beam source. Also within the system 400 is a neutralizer 440 operably connected to both the first ion source 410 and the second ion source 430.

The control logic of the neutralizer 440 receives requests from the individual source control logics, per their algorithms, and provides the desired neutralizer operation and status in response.

Particularly, a logical controller 450 of the neutralizer 440 receives a request from a control system 412 of the first ion source 410 at module 442 to provide electrons to enable ignition of the plasma at the first ion source 410 and to neutralize the ion beam from the first ion source 410 at a module 444. The logical controller 450 may be, for example, hardware, firmware, or instructions in software. The neutralizer 440 also receives a request from a control system 432 of the second ion source 430 at module 446 to provide electrons to enable ignition of the plasma at the second ion source 430 and to neutralize the ion beam from the second ion source 430 at a module 448. The requests to the modules 442, 444, 446, 448 are aggregated by the logical controller 450, which utilizes a control logic to address the requests from each of the modules 442, 444, 446, 448. In some systems, the control logic of the neutralizer 440 prioritizes neutralization of an assist beam over ignition and over neutralization of a deposition beam.

Electrons, depicted as a cloud in FIG. 4, are emitted from the neutralizer 440 and migrate to where needed.

It is noted that the neutralizer 440 is shown positioned approximately equidistant between the first ion source 410 and the second ion source 430, however in many configurations, the neutralizer 440 is positioned closer to one source than the other (typically, closer to the source that is the priority source) and may not be physically between the sources but offset toward a side of the system.

Thus, described herein is a system having one neutralizer for two ion sources. For systems having more than two sources, one neutralizer could be used for more than two ion sources; for example, if three ion sources are present, one neutralizer can be used for the three ion sources. One neutralizer can be used for any number of ion sources, with the neutralizer having an appropriate control system, positioning, and orientation. It is not necessary that the same neutralizer be used for all of the ion sources in a system. For example, in systems with three ion sources, one neutralizer can be used for two of the sources, and a second neutralizer can be used for the third source. Other arrangements are possible.

Described above are processes where a request is sent by an ion source to the neutralizer for the neutralizer to provide electrons. This request is to (1) provide low-energy electrons to the first ion beam source to enable ignition of a first ion beam, (2) provide low-energy electrons to the second ion beam source to enable ignition of a second ion beam, (3) neutralize the first ion beam, or (4) neutralize the second ion beam. The neutralizer can act on and accomplish all four actions.

Further, the description above provides the neutralizer with control logic that aggregates requests from the two ion sources or ion systems. Such control logic may include various software elements, such as software components, programs, applications, computer programs, application programs, system programs, machine programs, operating system software, middleware, firmware, software modules, routines, subroutines, operation segments, methods, procedures, software interfaces, application program interfaces (API), instruction sets, computing code, computer code, code segments, computer code segments, words, values, symbols, or any combination thereof. Executable computer program instructions may include any suitable types of code, such as source code, compiled code, interpreted code, executable code, static code, dynamic code, and the like. The executable computer program instructions may be implemented according to a predefined computer language, manner, or syntax, for instructing a computer to perform a particular operation segment. The instructions may be implemented using any suitable high-level, low-level, object-oriented, visual, compiled, and/or interpreted programming language.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

Various features and details have been provided in the multiple designs described above. It is to be understood that any features or details of one design may be utilized for any other design, unless contrary to the construction or configuration. Any variations may be made.

The above specification and examples provide a complete description of the structure and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about,” whether or not the term “about” is immediately present. Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

What is claimed is:

1. An ion beam deposition system comprising:
a deposition system comprising a deposition beam source;
an assist system comprising an assist beam source; and
a neutralizer configured to provide low-energy electrons to the deposition system upon receipt of a request from the deposition system and to the assist system upon receipt of a request from the assist system.

2. The system of claim 1, wherein the neutralizer is configured to:
enable igniting a plasma to produce an ion beam from the deposition beam source;
enable igniting a second plasma to produce an assist beam from the assist beam source;
neutralize the ion beam; and
neutralize the assist beam.

3. The system of claim 1, wherein the neutralizer has control logic configured to aggregate the request from the deposition system and the request from the assist system.

4. The system of claim 1, wherein the neutralizer has control logic configured to prioritize a request to neutralize the assist beam over other requests.

5. The system of claim 1, wherein the neutralizer is physically located between the deposition beam source and the assist beam source.

6. The system of claim 5, wherein the neutralizer is physically located closer to the assist beam source than to the deposition beam source.

7. The system of claim 1, wherein the neutralizer configured to provide low-energy electrons to the deposition system and to the assist system is an only neutralizer in the system.

8. The system of claim 1 further comprising a third ion source and a second neutralizer configured to provide low-energy electrons to the third ion source.

9. An ion beam deposition system comprising:
a first ion beam source;
a second ion beam source; and
a neutralizer configured to, upon receipt of a request, independently:
provide low-energy electrons to the first ion beam source to enable production of a first ion beam;
provide low-energy electrons the second ion beam source to enable production of a second ion beam;
neutralize the first ion beam; and
neutralize the second ion beam.

10. The system of claim 9, wherein the neutralizer has control logic configured to aggregate requests from the first ion beam source and the second ion beam source.

11. The system of claim 9, wherein the neutralizer has control logic configured to prioritize a request to neutralize the first ion beam over other requests.

12. The system of claim 9, wherein the neutralizer is physically located between the first ion beam source and the second ion beam source.

13. The system of claim 12, wherein the neutralizer is physically located closer to one of the first ion beam source and the second ion beam source than to the other.

14. A neutralizer in an assisted ion beam deposition system, the neutralizer configured to, upon receipt of a request:
enable igniting a plasma to produce an ion beam from a deposition beam source;
enable igniting a second plasma to produce an assist beam from an assist beam source;
neutralize the ion beam; and
neutralize the assist beam.

15. The neutralizer of claim 14 comprising control logic configured to aggregate requests from the deposition beam source and the assist beam source.

16. The neutralizer of claim 14 comprising control logic configured to prioritize a request to neutralize the assist beam over other requests.
